(19) United States
(12) Patent Application Publication
(10) Pub. No.: US 2018/0019232 A1
(43) Pub. Date: Jan. 18, 2018

(54) LIGHT EMITTING COMPONENT

(71) Applicant: Genesis Photonics Inc., Tainan City (TW)

(72) Inventors: Yi-Ru Huang, Tainan City (TW); Tung-Lin Chuang, Tainan City (TW); Chih-Ming Shen, Tainan City (TW); Sheng-Tsung Hsu, Tainan City (TW); Kuan-Chieh Huang, New Taipei City (TW); Jing-En Huang, Tainan City (TW)

(73) Assignee: Genesis Photonics Inc., Tainan City (TW)

(21) Appl. No.: 15/715,138

(22) Filed: Sep. 25, 2017

Related U.S. Application Data
(63) Continuation of application No. 15/045,264, filed on Feb. 17, 2016.
(60) Provisional application No. 62/116,923, filed on Feb. 17, 2015.

(51) Int. Cl. H01L 25/075; H01L 33/10; H01L 33/20; H01L 33/38; H01L 33/40; H01L 33/46; H01L 33/50; H01L 33/52; H01L 33/56; H01L 33/62; H01L 33/58; H01L 33/42; H01L 33/54; H01L 33/00

(52) U.S. Cl. CPC H01L 25/0753; H01L 33/58; H01L 33/10; H01L 33/20; H01L 33/382; H01L 33/405; H01L 33/42; H01L 33/46; H01L 33/507; H01L 33/52; H01L 33/56; H01L 33/62; H01L 33/0095; H01L 33/54; H01L 2224/48091; H01L 2224/48247; H01L 2224/48257; H01L 2933/0058; H01L 2224/73265; H01L 2933/0016; H01L 2933/0025; H01L 2933/005; H01L 2224/49107

(57) ABSTRACT

A light emitting component includes an epitaxial structure, an adhesive layer, a first reflective layer, a second reflective layer, a block layer, a first electrode and a second electrode. The epitaxial structure includes a substrate, a first semiconductor layer, a light emitting layer and a second semiconductor layer. The adhesive layer is disposed on the second semiconductor layer of the epitaxial structure. The first reflective layer is disposed on the adhesive layer. The second reflective layer is disposed on the first reflective layer and extended onto the adhesive layer. A projection area of the second reflective layer is larger than a projection area of the first reflective layer. The block layer is disposed on the second reflective layer. The first electrode is electrically connected to the first semiconductor layer. The second electrode is electrically connected to the second semiconductor layer.

### CROSS REFERENCE TO RELATED APPLICATION

This application is a continuation application of and claims the priority benefit of U.S. application Ser. No. 15/045,264, filed on Feb. 17, 2016, now pending, which claims the priority benefit of U.S. Provisional Application No. 62/116,923, filed on Feb. 17, 2015. The entirety of each of the above-mentioned patent applications is hereby incorporated by reference herein and made a part of specification.

### BACKGROUND OF THE INVENTION

### 1. Field of the Invention

The disclosure relates to a light emitting component and, more particularly, to a light emitting component capable of increasing a reflective area effectively.

### 2. Description of the Prior Art

Referring to FIG. 1, FIG. 1 is a schematic view illustrating a light emitting component 1 of prior art. As shown in FIG. 1, the light emitting component 1 comprises an epitaxial structure 10, an ohmic contact layer 12, a reflective layer 14, a block layer 16 and two electrodes 18, wherein the ohmic contact layer 12, the reflective layer 14, the block layer 16 and the electrodes 18 are disposed on the epitaxial structure 10. The reflective layer 14 is used to reflect light emitted by a light emitting layer 100 of the epitaxial structure 10. The block layer 16 is used to absorb light. In general, a material of the reflective layer 14 is silver or silver alloy with high reflectance. Since the chemical property of silver is very active, silver is unstable and diffuses randomly under high temperature. Accordingly, in the prior art, the area of the reflective layer 14 used to be limited within a certain range, so as to prevent from the reflective layer 14 diffusing to the epitaxial structure 10 due to elevated temperature during manufacture process and avoid the light emitting performance being affected. Accordingly, the reflective area of the reflective layer 14 is also limited to reflect limited light, such that the entire light emitting efficiency of the light emitting component 1 cannot be enhanced effectively.

### SUMMARY OF THE INVENTION

The disclosure provides a light emitting component capable of increasing a reflective area effectively, so as to solve the aforementioned problems.

The light emitting component of the disclosure comprises an epitaxial structure, an adhesive layer, a first reflective layer, a second reflective layer, a block layer, a first electrode and a second electrode. The epitaxial structure comprises a substrate, a first semiconductor layer, a light emitting layer and a second semiconductor layer. The adhesive layer is disposed on the second semiconductor layer of the epitaxial structure. The first reflective layer is disposed on the adhesive layer. The second reflective layer is disposed on the first reflective layer and extends onto the adhesive layer. A direction from the second reflective layer to the epitaxial structure is defined as a projection direction. A projection area of the second reflective layer in the projection direction is larger than a projection area of the first reflective layer in the projection direction. The block layer disposed on the second reflective layer is electrically conductive. The first electrode is electrically connected to the first semiconductor layer. The second electrode is electrically connected to the second semiconductor layer.

According to an embodiment of the disclosure, a material of the first reflective layer may be silver or silver alloy and a material of the second reflective layer may be non-silver metal, non-silver alloy or essentially consists of non-silver multiple metal layers, wherein a reflectance of the first reflective layer is larger than a reflectance of the second reflective layer and the reflectance of the second reflective layer is larger than or equal to 80%.

According to another embodiment of the disclosure, a material of the first reflective layer is aluminum or aluminum alloy and a material of the second reflective layer is non-metal material or essentially consists of multiple insulating layers (e.g. including, but not limited to, a Bragg reflective layer), wherein a reflectance of the second reflective layer is larger than a reflectance of the first reflective layer and the reflectance of the second reflective layer is larger than or equal to 80%.

As to the above mentioned, the disclosure provides to dispose the second reflective layer on the first reflective layer and extend the second reflective layer to the adhesive layer, such that the projection area of the second reflective layer is larger than the projection area of the first reflective layer. In other words, the disclosure provides that the first reflective layer with active chemical property (e.g. silver or silver alloy) is disposed on the adhesive layer within a certain area in advance, so as to prevent from the material of the first reflective layer diffusing to the epitaxial structure due to elevated temperature during manufacture process. Then, the second reflective layer with less active chemical property (e.g. non-silver metal, non-silver alloy or insulating material) is disposed on the first reflective layer and is extended onto the adhesive layer. Accordingly, the disclosure provides that the entire light emitting efficiency of the light emitting component can be enhanced by using the second reflective layer to increase the total reflective area effectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a light emitting component of prior art.

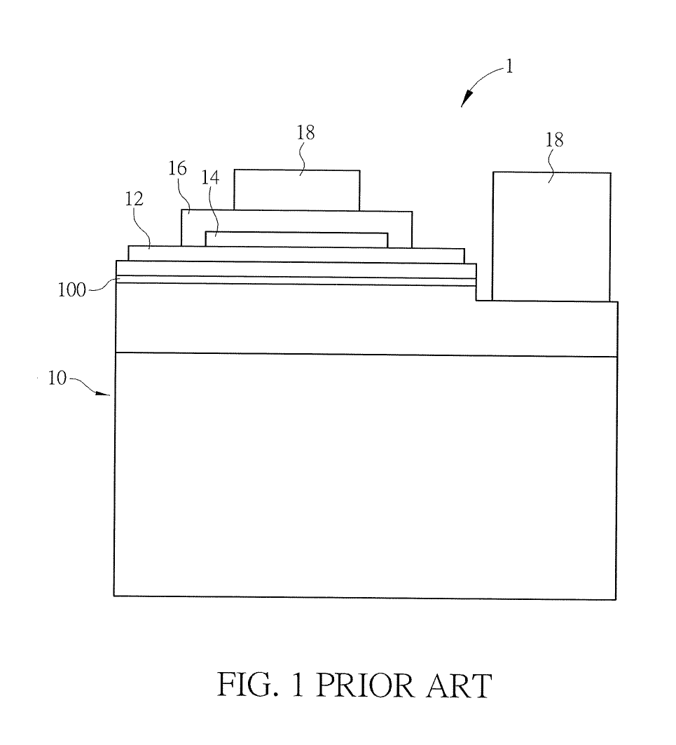

FIG. 2 is a schematic view illustrating a light emitting component according to a first embodiment of the disclosure.

FIG. 3 is a schematic view illustrating a light emitting component according to a second embodiment of the disclosure.

FIG. 4 is a schematic view illustrating a light emitting component according to a third embodiment of the disclosure.

FIG. 5 is a schematic view illustrating a light emitting component according to a fourth embodiment of the disclosure.

### DETAILED DESCRIPTION

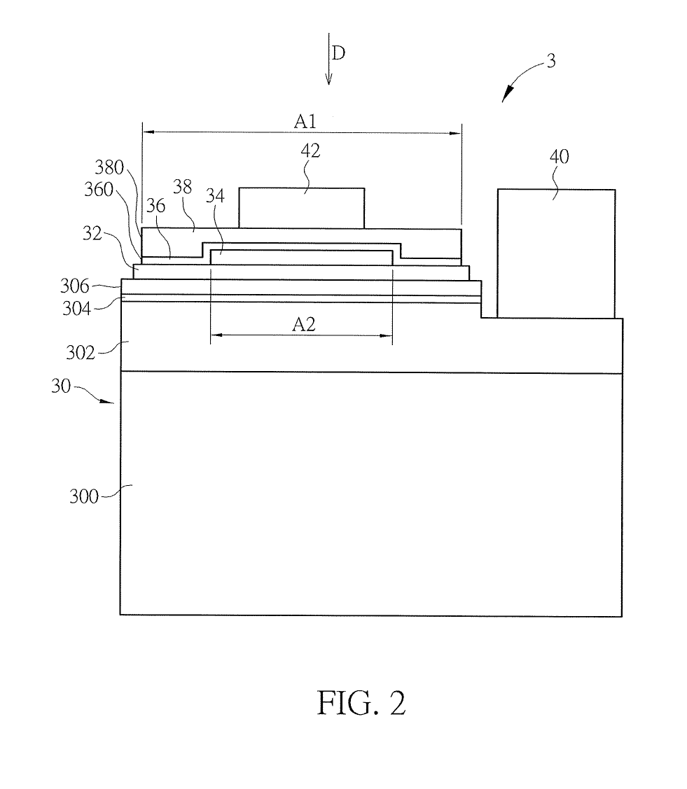

Referring to FIG. 2, FIG. 2 is a schematic view illustrating a light emitting component 3 according to a first embodiment of the disclosure. As shown in FIG. 2, the light emitting component 3 comprises an epitaxial structure 30, an adhesive layer 32, a first reflective layer 34, a second reflective layer 36, a block layer 38, a first electrode 40 and a second electrode 42. The epitaxial structure 30 comprises a substrate 300, a first semiconductor layer 302, a light emitting layer 304 and a second semiconductor layer 306, wherein the first semiconductor layer 302 is located on the substrate 300, the light emitting layer 304 is located on the first semiconductor layer 302, and the second semiconductor layer 306 is located on the light emitting layer 304. A material of the substrate 300 may be, but not limited to, a sapphire. The first electrode 40 is electrically connected to the first semiconductor layer 302 and the second electrode 42 is electrically connected to the second semiconductor layer 306. The first semiconductor layer 302 may be an N-type semiconductor layer (e.g. N-type GaN layer) and the second semiconductor layer 306 may be a P-type semiconductor layer (e.g. P-type GaN layer). At this time, the first electrode 40 is an N-type electrode and the second electrode 42 is a P-type electrode.

The adhesive layer 32 is disposed on the second semiconductor layer 306 of the epitaxial structure 30. In this embodiment, the adhesive layer 32 may be a metal film or a metal oxide layer such as indium tin oxide (ITO), wherein the thickness of the metal film is smaller than 20 nm. The first reflective layer 34 is disposed on the adhesive layer 32. In this embodiment, a material of the first reflective layer 34 may be silver or silver alloy. The second reflective layer 36 is disposed on the first reflective layer 34 and extended onto the adhesive layer 32. In this embodiment, a material of the second reflective layer 36 may be non-silver metal, non-silver alloy or essentially consists of multiple metal layers, such as aluminum or aluminum alloy. The block layer 38 is disposed on the second reflective layer 36 and has electrical conductivity. In this embodiment, a material of the block layer 38 may be platinum, gold, tungsten, titanium or titanium-tungsten alloy. Furthermore, the second reflective layer 36 and the block layer 38 may be formed in one same process, such that a side surface 360 of the second reflective layer 36 and a side surface 380 of the block layer 38 are planar. The second electrode 42 is disposed on the block layer 38, so as to be electrically connected to the second semiconductor layer 306 of the epitaxial structure 30 through the block layer 38, the second reflective layer 36 and the adhesive layer 32.

In another embodiment, a material of the first reflective layer 34 may be aluminum or aluminum alloy, and a material of the second reflective layer 36 may be non-silver metal, non-silver alloy or essentially consists of multiple insulating layers, wherein the block layer 38 is disposed on the second reflective layer 36 and has no electrical conductivity. A material of the block layer 38 may be the same to a material of the second reflective layer 36. The block layer 38 and the second reflective layer 36 may be formed in one same process. The second electrode 42 is disposed on the block layer 38 and electrically connected to the second semiconductor layer 306 of the epitaxial structure 30.

As shown in FIG. 2, a direction from the second reflective layer 36 to the epitaxial structure 30 is defined as a projection direction D. Since the second reflective layer 36 is disposed on the first reflective layer 34 and extended onto the adhesive layer 32, a projection area Al of the second reflective layer 36 in the projection direction D is larger than a projection area A2 of the first reflective layer 34 in the projection direction D, and the ratio of the projection area A2 of the first reflective layer 34 in the projection direction D to a projection area A4 of the light emitting layer 304 in the projection direction D is smaller than 30%. In one embodiment, the ratio of the projection area A2 of the first reflective layer 34 in the projection direction D to the projection area A4 of the light emitting layer 304 in the projection direction D may be smaller than 10%. The disclosure provides that the first reflective layer 34 with active chemical property (e.g. silver or silver alloy) is disposed on the adhesive layer 32 within a certain area in advance, so as to prevent from the material of the first reflective layer 34 diffusing to the epitaxial structure 30 due to elevated temperature during manufacture process. Then, the second reflective layer 36 with less active chemical property (e.g. non-silver metal or non-silver alloy) is disposed on the first reflective layer 34 and extended onto the adhesive layer 32. Accordingly, the disclosure provides that the entire light emitting efficiency of the light emitting component 3 can be enhanced by utilizing the second reflective layer 36 to increase the total reflective area effectively. In this embodiment, a reflectance of the second reflective layer 36 is larger than a reflectance of the block layer 38, and the reflectance of the second reflective layer 36 is larger than or equal to 80%.

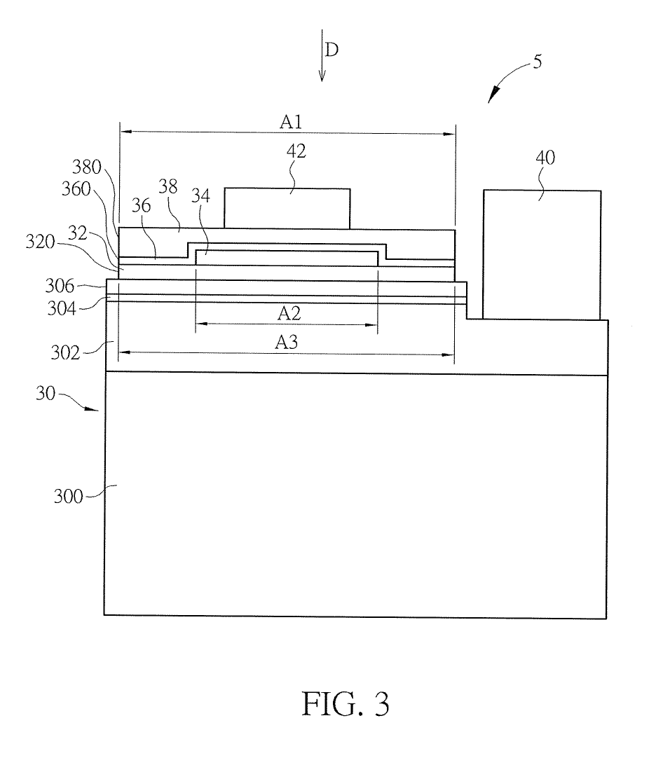

Referring to FIG. 3 along with FIG. 2, FIG. 3 is a schematic view illustrating a light emitting component 5 according to a second embodiment of the disclosure. The main difference between the light emitting component 5 and the aforementioned light emitting component 3 is that, in the light emitting component 5, the side surface 360 of the second reflective layer 36, the side surface 380 of the block layer 38 and a side surface 320 of the adhesive layer 32 are planar. In other words, the projection area A1 of the second reflective layer 36 in the projection direction D may be equal to a projection area A3 of the adhesive layer 32 in the projection direction D, and the ratio of the projection area A2 of the first reflective layer 34 in the projection direction D to the projection area A4 of the light emitting layer 304 in the projection direction D is smaller than 30%. In an embodiment, the ratio of the projection area A2 of the first reflective layer 34 in the projection direction D to the projection area A4 of the light emitting layer 304 in the projection direction D may be smaller than 10%, so as to further increase the total reflective area.

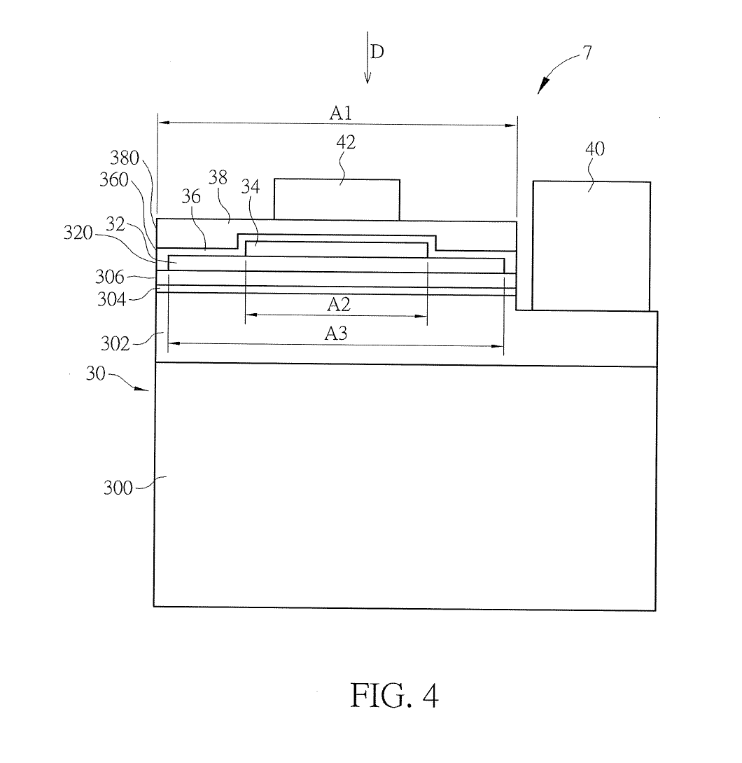

Referring to FIG. 4 along with FIG. 3, FIG. 4 is a schematic view illustrating a light emitting component 7 according to a third embodiment of the disclosure. The main difference between the light emitting component 7 and the aforementioned light emitting component 5 is that the second reflective layer 36 of the light emitting component 7 is further extended onto the second semiconductor layer 306 of the epitaxial structure 30, such that the projection area A1 of the second reflective layer 36 in the projection direction D is larger than the projection area A3 of the adhesive layer 32 in the projection direction D, and the ratio of the projection area A2 of the first reflective layer 34 in the projection direction D to the projection area A4 of the light emitting layer 304 in the projection direction D is smaller than 30%. In one embodiment, the ratio of the projection area A2 of the first reflective layer 34 in the projection direction D to the projection area A4 of the light emitting layer 304 in the projection direction D may be smaller than 10%. Accordingly, the total reflective area can be further increased.

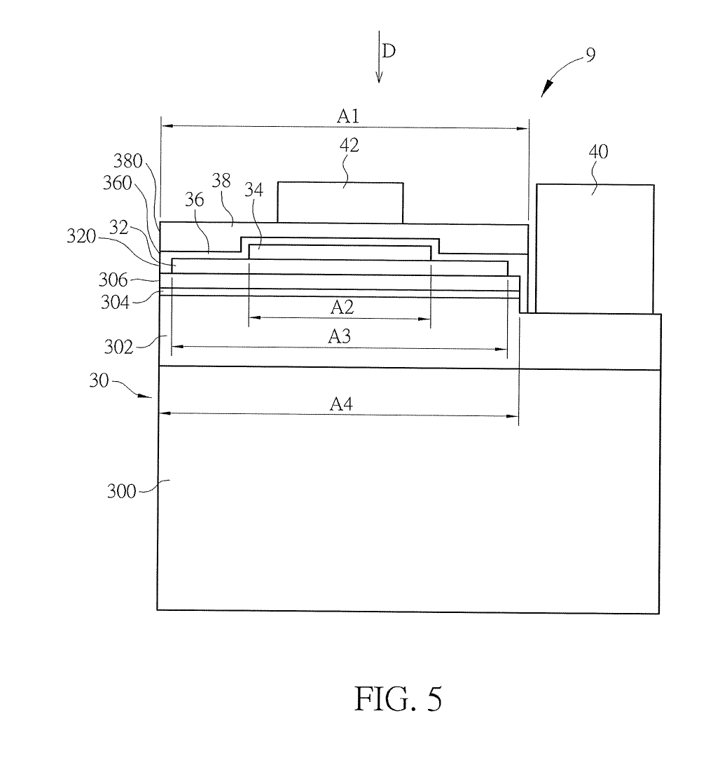

Referring to FIG. 5 along with FIG. 4, FIG. 5 is a schematic view illustrating a light emitting component 9 according to a fourth embodiment of the disclosure. A material of the second reflective layer 36 may be non-silver metal, non-silver alloy or essentially consists of multiple insulating layers, for example, including but not limited to a Bragg reflective layer. A material of the first reflective layer 34 may be aluminum or aluminum alloy, wherein the block layer 38 is disposed on the second reflective layer 36 and has no electrical conductivity. A material of the block layer 38 may be the same to a material of the second reflective layer 36. The block layer 38 and the second reflective layer 36 may be formed in one same process. The second electrode 42 is disposed on the block layer 38 and electrically connected to the second semiconductor layer 306 of the epitaxial structure 30. The main difference between the light emitting component 9 and the aforementioned light emitting component 7 is that the second reflective layer 36 of the light emitting component 9 is further extended onto the first semiconductor layer 302 of the epitaxial 30, such that the projection area A1 of the second reflective layer 36 in the projection direction D is larger than the projection area A4 of the light emitting layer 304 in the projection direction D, and the ratio of the projection area A2 of the first reflective layer 34 in the projection direction D to the projection area A4 of the light emitting layer 304 in the projection direction D is smaller than 30%. In one embodiment, the ratio of the projection area A2 of the first reflective layer 34 in the projection direction D to the projection area A4 of the light emitting layer 304 in the projection direction D may be smaller than 10%. Accordingly, the total reflective area can be further increased.

As the above mentioned, the disclosure provides that the second reflective layer is disposed on the first reflective layer and extended to the adhesive layer, such that the projection area of the second reflective layer is larger than the projection area of the first reflective layer. In other words, the disclosure provides that the first reflective layer with active chemical property (e.g. silver or silver alloy) is disposed on the adhesive layer within a certain area in advance, so as to prevent from the material of the first reflective layer diffusing to the epitaxial structure due to elevated temperature during manufacture process. Then, the disclosure provides that the second reflective layer with less active chemical property (e.g. non-silver metal, non-silver alloy or insulating material) is disposed on the first reflective layer and extended onto the adhesive layer. Accordingly, the disclosure provides that the entire light emitting efficiency of the light emitting component can be enhanced by using the second reflective layer to increase the total reflective area effectively.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting component comprising:
an epitaxial structure comprising a substrate, a first semiconductor layer disposed on the substrate, a light emitting layer and a second semiconductor layer disposed on the first semiconductor layer and exposed the first semiconductor layer;
an adhesive layer disposed on the second semiconductor layer;
a metal layer disposed on the adhesive layer and exposed the adhesive layer;
a Bragg reflective layer covering metal layer, the exposed adhesive layer, a side surface of the second semiconductor layer and at least a portion of the exposed first semiconductor layer;
a block layer, comprising a metal, covering at least a portion of the Bragg reflective layer and not configured for electrical conductivity;
a first electrode electrically connected to the first semiconductor layer; and
a second electrode electrically connected to the second semiconductor layer via the metal layer and the adhesive layer.

2. The light emitting component of claim 1, wherein a material of the metal layer is silver, silver alloy, aluminum or aluminum alloy.

3. The light emitting component of claim 1, wherein a material of the block layer is platinum, gold, wolfram, titanium or titanium-tungsten alloy.

4. The light emitting component of claim 1, wherein the adhesive layer is a metal film or a metal oxide layer.

5. The light emitting component of claim 1, wherein the second electrode is electrically connected to the metal layer through the block layer.

6. A light emitting component comprising:
an epitaxial structure comprising a substrate, a first semiconductor layer disposed on the substrate, a light emitting layer and a second semiconductor layer disposed on the first semiconductor layer and exposed the first semiconductor layer;
an adhesive layer disposed on the second semiconductor layer;
a first metal layer disposed on the adhesive layer and exposed the adhesive layer;
a second metal layer covering first metal layer, the exposed adhesive layer, a side surface of the second semiconductor layer and at least a portion of the exposed first semiconductor layer;
a block layer substantially covering an entire upper surface of the second metal layer;
a first electrode electrically connected to the first semiconductor layer; and
a second electrode disposed on the block layer and electrically connected to the second semiconductor layer via the first metal layer and the adhesive layer.

7. The light emitting component of claim 6, wherein a material of the first metal layer is silver, silver alloy, and a material of the second metal layer is non-silver metal, non-silver alloy or essentially consists of multiple metal layers.

8. The light emitting component of claim 6, wherein a material of the first metal layer is aluminum or aluminum alloy, and a material of the second metal layer is non-silver metal, or non-silver alloy.

9. The light emitting component of claim 6, wherein the adhesive layer is a metal film or a metal oxide layer.

10. The light emitting component of claim 6, wherein the second electrode is electrically connected to the first metal layer via the block layer and the second metal layer.
